(19) United States
(12) Patent Application Publication
(10) Pub. No.: US 2019/0239371 A1
(43) Pub. Date: Aug. 1, 2019

(54) Cover and Box Body

(71) Applicant: Yazaki Corporation, Tokyo (JP)

(72) Inventors: Isanori Shimizu, Makinohara-shi (JP); Kouichi Ooyama, Makinohara-shi (JP); Masakuni Samejima, Makinohara-shi (JP); Takeo Koga, Makinohara-shi (JP)

(73) Assignee: Yazaki Corporation, Tokyo (JP)

(21) Appl. No.: 16/262,074

(22) Filed: Jan. 30, 2019

(30) Foreign Application Priority Data
Jan. 31, 2018 (JP) 2018-015655

(51) Int. Cl. H05K 5/03; H05K 5/06; H05K 7/20

(52) U.S. Cl. CPC H05K 5/03; H05K 5/064; B60T 8/17; H05K 7/20409; H05K 7/20854

(57) ABSTRACT

A cover (1) closes an opening portion of a case (2). The opening portion is formed of resin and belonging to the case (2). The cover (1) includes a resin member (10) having a frame portion having a shape corresponding to the opening portion, a metal member (20) provided in the resin member (10) and closing a hollow place defined by the frame portion, and a watertight member (30) sealing a contact place between the resin member (10) and the metal member (20). The resin member (10) and the metal member (20), in the contact place, define a concave portion by standing a pair of wall portions (11, 13) belonging to the resin member (10) erectly on the metal member (20). The watertight member (30) is provided inside the concave portion.

### CROSS-REFERENCES TO RELATED APPLICATION(S)

This application is based on and claims priority from Japanese Patent Application No. 2018-015655 filed on Jan. 31, 2018, and the entire contents of which are incorporated herein by reference.

### BACKGROUND

### Field of the Invention

The present invention relates to a cover for closing an opening portion of a case, and a box body including the cover.

### Description of Related Art

A box body in which an opening portion of a resin case is covered with a cover has been known in the background art. Specifically, in one of box bodies in the background art, an opening portion of a resin case and a cover made from resin are welded under vibration to seal the box body.

As for details of the above protector, refer to JP 2008-166382 A, JP 2012-209308 A, JP 2009-295362 A, JP 2008-306048 A, JP 2007-305721 A, JP 2006-287065 A, and JP 5617011 B.

### SUMMARY

An example of the aforementioned box body includes an ABS (Antilock Brake System) unit for a vehicle. In this unit, a circuit board for system control or a solenoid coil (device) for operating a valve for opening/closing a hydraulic circuit including a brake device etc. is received in a resin case (box body). The temperature inside the resin case tends to increase due to working heat of the unit. It is preferable that such working heat is released from the inside of the resin case to the outside. However, in the aforementioned box body in the background art, the inside of the box body is entirely covered with a resin material. It is desired to improve the box body in terms of heat dissipation.

An object of the invention is to provide a cover superior in heat dissipation from the inside of a case, and a box body provided with the cover.

Embodiments of the present invention provide the following items [1] to [4]:

[1] A cover for closing an opening portion of a case, the opening portion being formed of resin and belonging to the case, the cover comprising:

a resin member having a frame portion having a frame shape corresponding to the opening portion;

a metal member being provided in the resin member and closing a hollow place defined by the frame portion; and

a watertight member sealing a contact place between the resin member and the metal member,

the resin member and the metal member, in the contact place, defining a concave portion by standing a pair of wall portions belonging to the resin member and facing each other at a preset distance erectly on the metal member,

the watertight member being provided inside the concave portion.

[2] The cover according to the item [1], wherein,

the resin member has a connection portion connecting the pair of wall portions over the watertight member provided in the concave portion, and the concave portion is formed continuously along the contact place,

the watertight member is made from a material being injectable into the contact place by a potting method.

[3] The cover according to the item [2], wherein,

the resin member has a structure in which the pair of wall portions are integrally formed through the connection portion or a structure in which the pair of wall portions are separated from each other and connected through the watertight member.

[4] The cover according to any one of the items [1] to [3], wherein,

the watertight member is provided in a place where the watertight member is not exposed to the outside when the cover is attached to the case.

According to first aspect of the invention, relating to the item [1], for example, the opening portion made from resin in the case can be bonded to the resin member (frame portion) of the cover by welding in the same manner as in the background art. In addition, the hollow place of the resin member (frame portion) is closed by the metal member. Accordingly, heat dissipation from the inside of the case is more excellent than in a case where the hollow place is closed by the resin member. Further, since the watertight member is provided, it is possible to suppress water or the like from entering the inside of the case through a gap between the resin material and the metal member forming the cover. In addition, the watertight member is provided in the concave portion formed by the pair of wall portion belonging to the resin member and the metal member, so that it is possible to improve the sealing property while suppressing positional displacement of the watertight member (particularly, leakage when a potting material is used as will be described later). When the watertight member is formed by using potting method, the water stop property in the contact place between the resin member and the metal member can be enhanced in spite of dimensional variations of the resin member and the metal member.

Thus, the cover having the aforementioned configuration has excellent heat dissipation from the inside of the resin case. Further, it is possible to suppress water from entering the inside of the resin case.

According to second aspect of the invention, relating to the item [2], the pair of wall portions forming the concave portion are connected to each other through the bridge-like connection portion to form the concave portion continuously along the contact place. Thus, a sealing material injected (potted) to the concave portion can flow through the concave portion to thereby seal the whole of the contact place (concave portion) by potting performed once. It is therefore possible to form the watertight member easily.

According to third aspect of the invention, relating to the item [3], the pair of wall portions are formed integrally, or formed separately and connected. Thus, the cover can be formed. The cover can be designed so that a most suitable production method taking the shape, dimensions, etc. of the cover into consideration can be selected.

According to fourth aspect of the invention, relating to the item [4], the watertight member is not exposed to the outside in the state where the cover has been attached to the case. Thus, the watertight member can be isolated from an external environment so that the water stop property thereof can be kept for a long time.

Embodiments of the present invention further provide the following item [5]:

[5] A box body comprising:

a case having an opening portion being formed of resin; and

a cover according to any one of the items [1] to [4], the cover being attached to the case to close the opening portion.

According to fifth aspect of the invention, relating to the item [5], for example, the opening portion made from resin in the case can be bonded to the resin member (frame portion) of the cover by welding in the same manner as in the background art. In addition, the hollow place of the resin member (frame portion) is closed by the metal member. Accordingly, heat dissipation from the inside of the case is more excellent than in a case where the hollow place is closed by the resin member. Further, since the watertight member is provided, it is possible to suppress water or the like from entering the inside of the case through a gap between the resin material and the metal member forming the cover. Particularly the watertight member is provided in the concave portion of the cover so that it is possible to improve the sealing property while suppressing positional displacement of the watertight member.

Accordingly, the box body having the aforementioned configuration has excellent heat dissipation from the inside thereof. Further, water can be suppressed from entering the inside of the box body.

According to the invention, it is possible to provide a cover and a box body having excellent heat dissipation from the inside of a resin case.

Several aspects of the invention have been described briefly above. The further details of the invention will be made clearer if the following description is read through with reference to the accompanying drawings.

### BRIEF DESCRIPTION OF THE DRAWINGS

FIG. 1A is a perspective view in which a cover according to an embodiment of the invention is observed from its rear side; FIG. 1B is a perspective view in which the cover is observed from its front side; FIG. 1C is a sectional view taken on line A-A in FIG. 1B; and FIG. 1D is an enlarged view of a portion B in FIG. 1C.

FIG. 2A is a plan view of a metal plate alone, which is insert-molded in the cover shown in FIGS. 1A-1D; FIG. 2B is a plan view of the cover shown in FIGS. 1A-1D; and FIG. 2C is a sectional view taken on line C-C in FIG. 2B.

FIG. 3 is a perspective view of a box body in which an opening portion of a resin case is covered with the cover shown in FIGS. 1A-1D.

FIG. 4 is an exploded perspective view of a cover according to a modification of the embodiment of the invention.

FIG. 5A is a perspective view in which the cover shown in FIG. 4 has been finished; and FIG. 5B is a sectional view taken on line D-D in FIG. 5A.

### DETAILED DESCRIPTION

### Embodiment

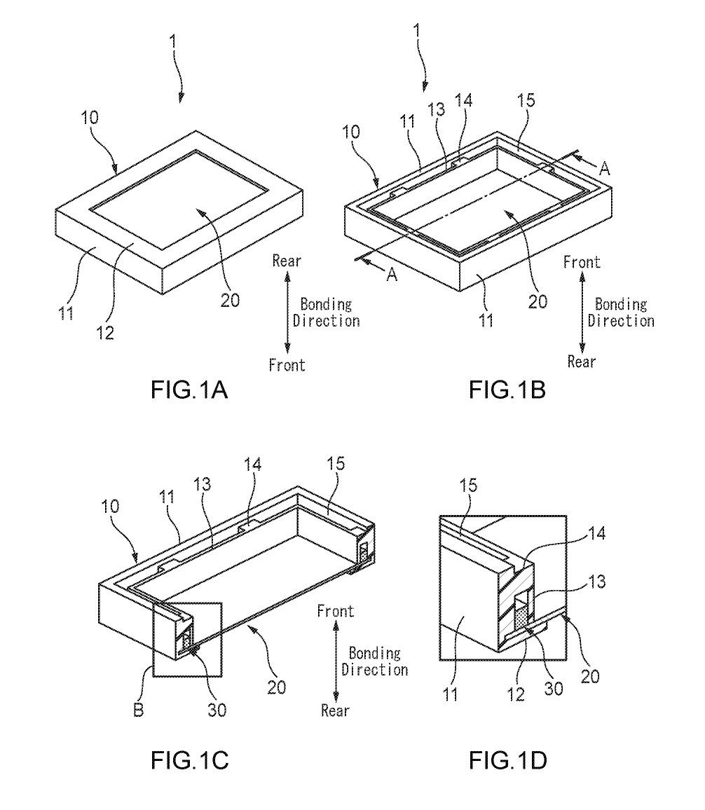

A cover 1 of a resin case 2 and a box body 3 according to an embodiment of the invention will be described below with reference to FIGS. 1A-1D, 2A-2C, and 3.

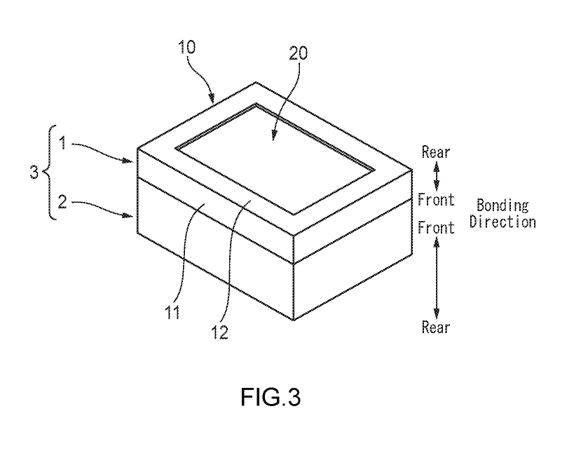

The cover 1 shown in FIGS. 1A-1D is a member for closing an opening portion (not shown) of the resin case 2 shown in FIG. 3. The cover 1 is bonded to the resin case 2 so as to close the opening portion of the resin case 2. Thus, the box body 3 is formed. An ABS (Antilock Brake System) unit for a vehicle is typically assumed as the box body 3.

For convenience of explanation, a “bonding direction”, a “front” and a “rear” will be defined in the following description as shown in FIGS. 1A-1D, 2A-2C, and 3. As is understood from FIG. 3, the front-rear direction in the cover 1 is opposite to the front-rear direction in the resin case 2. When the cover 1 and the resin case 2 are bonded so that the front end face of the cover 1 and the front end face of the resin case 2 are opposed to each other and brought into contact with each other, the box body 3 in which the front opening portion of the resin case 2 is closed by the cover 1 can be obtained.

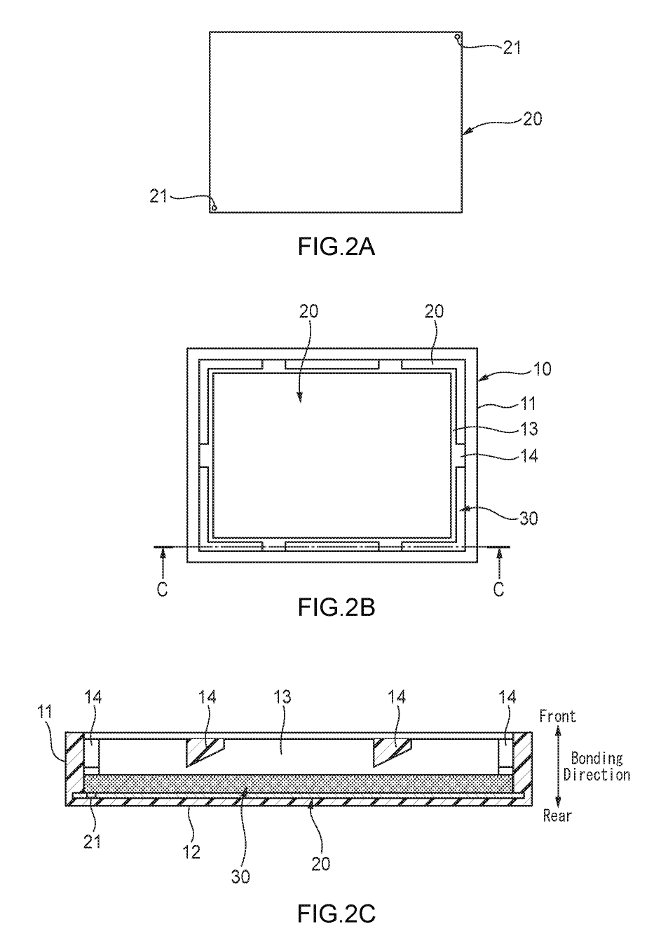

As shown in FIGS. 1A-1D and FIGS. 2A-2C, the cover 1 is constituted by a rectangular frame 10 and a metal plate 20. The frame 10 is made from resin. The metal plate 20 is insert-molded in the frame 10 so as to close a hollow place defined by the frame 10. The frame shape of the frame 10 corresponds to the shape of the front opening portion of the resin case 2. As shown in FIG. 2A, the metal plate 20 has a shape like a rectangular flat sheet, and positioning holes (through holes) 21 are formed at, of the four corners, two places located on a diagonal line.

As shown in FIG. 1C, FIG. 1D, FIG. 2B and FIG. 2C, the frame 10 is a molded body integrally having an outer wall portion 11, a rear wall portion 12, an inner wall portion 13, and connection portions 14.

The outer wall portion 11 is a rectangular frame-like body which is formed by insert molding of the metal plate 20 so as to be integrated with the whole circumference of an outer edge portion of the metal plate 20 and to cover the whole circumference of the outer edge portion. The outer wall portion 11 projects frontward from the whole circumference of the outer edge portion. The rear wall portion 12 is a rectangular frame-like body which extends inward in a planar direction perpendicular to the bonding direction by a preset distance from the whole circumference of a rear end portion of the outer wall portion 11. The rear wall portion 12 is in contact with a rear-side face of the outer edge portion of the metal plate 20.

The inner wall portion 13 is a rectangular frame-like body which is located to face the whole circumference of an inner wall surface of the outer wall portion 11 at a preset distance. The inner wall portion 13 projects frontward from a front-side face of the outer edge portion of the metal plate 20. When the outer wall portion 11 and the inner wall portion 13 are provided erectly in front of the metal plate 20 so as to face each other at a preset distance all over their circumferences in this manner, a rectangular annular concave portion having an opening 15 in its front is defined by the inner wall of the outer wall portion 11, the front-side face of the metal plate 20, and the outer wall of the inner wall portion 13.

The connection portions 14 are parts which are located at a plurality of circumferential places (six places in this embodiment) between the outer wall portion 11 and the inner wall portion 13, so that each of the connection portions 14 serves as a bridge connecting a front-side part of the inner wall of the outer wall portion 11 with a front-side part of the outer wall of the inner wall portion 13. Thus, the opening 15 of the aforementioned annular concave portion is circumferentially divided into a plurality of pieces by the connection portions 14 while a part of the annular concave portion located behind the connection portions 14 is circumferentially continuous all over its whole circumference. Incidentally, as shown in FIG. 2C, a rear-side face of each connection portion 14 is slanted circumferentially from a planar direction perpendicular to the bonding direction. This is to use a so-called “inner slide structure” to avoid a so-called “undercut” when the frame 10 provided with the outer wall portion 11, the rear wall portion 12, the inner wall portion 13 and the connection portion 14 is integrally molded.

As shown in FIG. 1C, FIG. 1D, FIG. 2B and FIG. 2C, the aforementioned annular concave portion (a part thereof at the rears of the connection portions 14) is filled with a potting agent 30 all over its whole circumference by potting. Thus, an annular contact place between the frame 10 and the metal plate 20 is sealed all over its whole circumference. In this manner, the potting agent 30 is provided at a place of the box body 3 which will not be exposed to the outside when the cover 1 is bonded with the resin case 2 to form the box body 3. Each of the connection portions 14 serves as a bridge connecting the outer wall portion 11 and the inner wall portion 13 so as to straddle an upper portion of the potting agent 30 charged into the aforementioned annular concave portion.

As described above, the aforementioned annular concave portion (a part thereof at the rears of the connection portions 14) is circumferentially continuous all over its whole circumference. Thus, when the potting agent 30 is injected (potted) from a preset place of the opening 15 of the aforementioned annular concave portion, the injected potting agent 30 flows through the aforementioned annular concave portion all over its whole circumference. As a result, the annular contact place between the frame 10 and the metal plate 20 can be sealed all over its whole circumference by the potting operation performed once.

In addition, the inner wall portion 13 opposed to the outer wall portion 11 is provided, and the annular concave portion defined by the outer wall portion 11 and the inner wall portion 13 is filled with the potting agent 30 by potting. Thus, the potting agent 30 can be suppressed from being displaced inward in the planar direction, as compared with a mode where the inner wall portion 13 is not provided. As a result, the use amount of the potting agent 30 can be suppressed to a minimum.

Specifically as shown in FIG. 3, in order to close the front opening portion of the resin case 2 with the aforementioned cover 1 to thereby obtain the box body 3, a front end face of the outer wall portion 11 of the frame 10 made from resin in the cover 1 is bonded with a front end face of the resin case 2. In this bonding, resin members are bonded with each other. Therefore, the bonding can be performed by use of vibration welding, laser welding, etc. Incidentally, the bonding may be performed by use of a bonding agent.

The resin case 2 internally receives a circuit board (not shown) mounted with a plurality of semiconductor elements (not shown) including a central processing unit (CPU) for performing ABS control, a device (not shown) such as a solenoid coil forming a hydraulic valve for opening/closing a hydraulic circuit including a brake device, etc. The device is controlled by the CPU mounted on the circuit board. A hollow place (not shown) facing the circuit board and the device is formed inside the resin case 2.

In the box body 3, working heat is generated from semiconductor elements mounted on the device or the circuit board during the operation of the device such as the solenoid coil received in the resin case 2. The working heat tends to be accumulated in the aforementioned hollow place. It is preferable that the working heat accumulated in the hollow place is released to the outside of the box body 3.

With respect to this point, a major part of the front opening portion of the resin case 2 is closed by the metal plate 20 of the cover 1 in the box body 3. Generally, metal is more excellent in thermal conductivity than resin. Accordingly, the working heat accumulated in the aforementioned hollow place is apt to be released to the outside of the box body 3 through the metal plate 20. To say other words, in the box body 3, heat dissipation is more excellent than in a case where the whole of the cover is formed out of a resin member and a major part of the front opening portion of the resin case 2 is closed by the resin member.

As described above, according to the cover 1 of the resin case 2 and the box body 3 according to the embodiment of the invention, the opening portion made from resin in the case 2 and the outer wall portion 11 of the frame 10 made from resin in the cover 1 can be bonded to each other by welding in the same manner as in the background art. In addition, the hollow place of the frame 10 is closed by the metal plate 20. Accordingly, heat dissipation from the inside of the resin case 2 is more excellent than in the case where the hollow place is closed by a resin member. Further, the annular contact place between the frame 10 and the metal plate 20 is sealed by the potting agent 30. Accordingly, water or the like can be suppressed from entering the inside of the resin case 2 through a gap between the resin material forming the frame 10 and the metal plate 20. In addition, the potting agent 30 is provided by potting in the annular concave portion formed by the outer wall portion 11 and the inner wall portion 13 belonging to the frame 10 made from the resin material and the metal plate 20. Accordingly, it is possible to improve the sealing property while suppressing positional displacement of the potting agent 30. When the potting agent 30 is charged by potting in this manner, the water stop property in the contact place between the frame 10 and the metal plate 20 can be enhanced in spite of dimensional variations of the frame 10 and the metal plate 20. In this manner, the cover 1 of the resin case 2 has excellent heat dissipation from the inside of the resin case 2. Further, water can be suppressed from entering the inside of the resin case 2.

Further, the outer wall portion 11 and the inner wall portion 13 of the frame 10 are connected through the bridge-like connection portions 14 so as to from the annular concave portion like a string. The potting agent 30 injected (potted) into a preset place of the annular concave portion can flow through the annular concave portion to thereby seal the whole of the contact place (annular concave portion) by potting performed once. Accordingly, the watertight member can be formed easily.

Further, the potting agent 30 is not exposed to the outside of the box body 3 in the state where the cover 1 has been attached to the resin case 2. Accordingly, the potting agent 30 can be isolated from the external environment so that the water stop property of the potting agent 30 can be kept for a long time.

### Other Embodiments

In addition, the invention is not limited to the aforementioned embodiments, but various modifications can be used within the scope of the invention. For example, the invention is not limited to the aforementioned embodiments, but changes, improvements, etc. can be made on the invention suitably. In addition, materials, shapes, dimensions, numbers, arrangement places, etc. of respective constituent elements in the aforementioned embodiments are not limited. Any materials, any shapes, any dimensions, any numbers, any arrangement places, etc. may be used as long as the invention can be attained.

For example, in the aforementioned embodiment, the contact place between the frame 10 and the metal plate 20 is sealed by the potting agent 30. However, the potting agent 30 may be replaced by a packing formed out of an elastic material such as rubber to seal the contact place.

Further, in the aforementioned embodiment, the cover 1 is formed so that the frame 10 can touch only the outer edge portion of the metal plate 20. However, the frame 10 may be designed to cover other parts than the outer edge portion of the metal plate 20. For example, the frame 10 may have a plurality of window-like hollow places, and the metal plate 20 may be provided to close the hollow places.

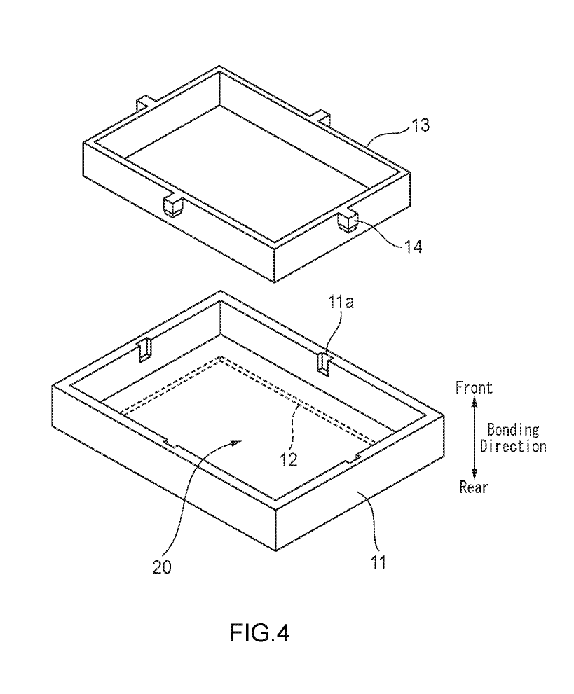

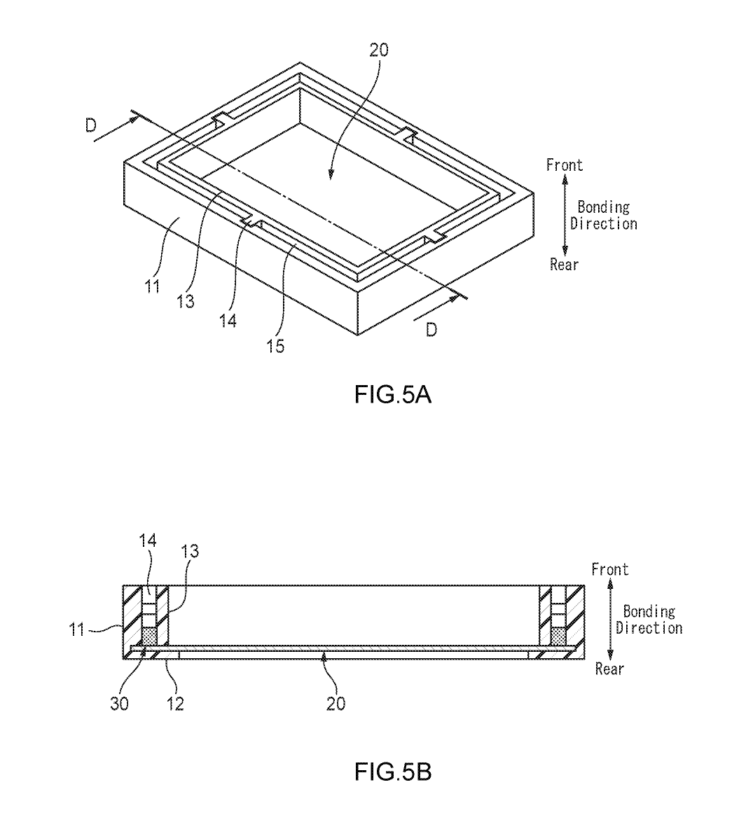

Further, in the aforementioned embodiment, the outer wall portion 11 and the inner wall portion 13 in the frame 10 are integrally molded (see FIGS. 1A-1D and FIGS. 2A-2C). However, as shown in FIG. 4 and FIGS. 5A-5B, the outer wall portion 11 and the inner wall portion 13 in the frame 10 may be formed as separate pieces.

In the example shown in FIG. 4 and FIGS. 5A-5B, a first frame-like body and a second frame-like body are prepared. The first frame-like body is made from resin and formed into a shape corresponding to the outer wall portion 11 and the rear wall portion 12. The metal plate 20 is insert-molded in the first frame-like body. The second frame-like body is made from resin and formed into a shape corresponding to the inner wall portion 13. In the first frame-like body, positioning grooves 11a are formed at a plurality of circumferential places (four places in this example) respectively in the inner wall of the outer wall portion 11. In the second frame-like body, boss portions 14 corresponding to the connection portions 14 are integrally formed at places corresponding to the grooves 11a in the outer wall of the inner wall portion 13 respectively, so as to project outward in the planar direction.

The second frame-like body is fitted to the first frame-like body so that the boss portions 14 of the second frame-like body are fitted into the grooves 11a of the first frame-like body. Thus, as shown in FIGS. 5A-5B, a frame having a shape equivalent to that of the frame 10 in the aforementioned embodiment can be obtained. The potting agent 30 is potted from an annular concave opening 15 defined between the outer wall portion 11 and the inner wall portion 13 in this frame. It is preferable that this potting is performed in a state where the second frame-like body is pressed rearward against the first frame-like body by a preset jig or the like so as to surely close the annular contact place between the first and second frame-like bodies.

Accordingly, the annular concave portion is filled with the potting agent 30 all over its whole circumference. When the potting agent 30 charged thus is solidified, the annular contact place between the first and second frame-like bodies is sealed all over its whole circumference, while the first and second frame-like bodies (that is, the outer wall portion 11 and the inner wall portion 13) are connected (fixed) to each other. As a result, a cover similar to the cover 1 in the aforementioned embodiment can be obtained.

Incidentally, the metal plate 20 is insert-molded in the first frame-like body having a shape corresponding to the outer wall portion 11 and the rear wall portion 12 in the example shown in FIG. 4 and FIGS. 5A-5B. However, the first frame-like body and the metal plate 20 may be prepared as separate pieces. In this configuration, the second frame-like body is fitted to the inside of the first frame-like body in a state where the metal plate 20 has been put on the rear wall portion 12 in the first frame-like body. Thus, a frame having a shape equivalent to that of the frame 10 in the aforementioned embodiment can be obtained.

Here, the features of the aforementioned embodiment of the cover 1 of the resin case 2 and the box body 3 according to the invention will be summarized and listed briefly in the following paragraphs [1] to [5].

[1] A cover (1) for closing an opening portion of a case (2), the opening portion being formed of resin and belonging to the case (2), the cover (1) comprising:

a resin member (10) having a frame portion having a frame shape corresponding to the opening portion;

a metal member (20) being provided in the resin member (10) and closing a hollow place defined by the frame portion; and

a watertight member (30) sealing a contact place between the resin member (10) and the metal member (20),

the resin member (10) and the metal member (20), in the contact place, defining a concave portion by standing a pair of wall portions (11, 13) belonging to the resin member (10) and facing each other at a preset distance erectly on the metal member (20),

the watertight member (30) being provided inside the concave portion.

[2] The cover (1) according to the item [1], wherein,

the resin member (10) has a connection portion (14) connecting the pair of wall portions (11, 13) over the watertight member (30) provided in the concave portion, and the concave portion is formed continuously along the contact place,

the watertight member (30) is made from a material being injectable into the contact place by a potting method.

[3] The cover (1) according to the item [2], wherein,

the resin member (10) has a structure in which the pair of wall portions (11, 13) are integrally formed through the connection portion (14) or a structure in which the pair of wall portions (11, 13) are separated from each other and connected through the watertight member (30).

[4] The cover (1) according to any one of the items [1] to [3], wherein,

the watertight member (30) is provided in a place where the watertight member (30) is not exposed to the outside when the cover (1) is attached to the case (2).

[5] A box body (3) comprising:

a case (2) having an opening portion being formed of resin; and

a cover (1) according to any one of the items [1] to [4], the cover (1) being attached to the case (2) to close the opening portion.

### REFERENCE SIGNS LIST

1 cover
2 resin case (case)
3 box body
10 frame (resin member)
11 outer wall portion (wall portion)
13 inner wall portion (wall portion)
14 connection portion
20 metal plate (metal member)
30 potting agent (watertight member)

1. A cover for closing an opening portion of a case, the opening portion being formed of resin and belonging to the case, the cover comprising:
a resin member having a frame portion having a frame shape corresponding to the opening portion;
a metal member being provided in the resin member and closing a hollow place defined by the frame portion; and
a watertight member sealing a contact place between the resin member and the metal member,
the resin member and the metal member, in the contact place, defining a concave portion by standing a pair of wall portions belonging to the resin member and facing each other at a preset distance erectly on the metal member,
the watertight member being provided inside the concave portion.

2. The cover according to claim 1, wherein,
the resin member has a connection portion connecting the pair of wall portions over the watertight member provided in the concave portion, and the concave portion is formed continuously along the contact place,
the watertight member is made from a material being injectable into the contact place by a potting method.

3. The cover according to claim 2, wherein,
the resin member has a structure in which the pair of wall portions are integrally formed through the connection portion or a structure in which the pair of wall portions are separated from each other and connected through the watertight member.

4. The cover according to claim 1, wherein,
the watertight member is provided in a place where the watertight member is not exposed to the outside when the cover is attached to the case.

5. A box body comprising:
a case having an opening portion being formed of resin; and
a cover according to claim 1, the cover being attached to the case to close the opening portion.
